(19) United States
(12) Patent Application Publication
(10) Pub. No.: US 2004/0037044 A1
(43) Pub. Date: Feb. 26, 2004

(54) Heat sink for surface mounted power devices

(76) Inventors: Alexander Cook, Dublin, OH (US); Stephen D. Speck, Pataskala, OH (US); James G. Campbell, Dublin, OH (US); Alexander Isurin, Dublin, OH (US); John Humphries, Lewis Center, OH (US)

Correspondence Address: THOMPSON HINE LLP, 10 W. BROAD ST., SUITE 700, COLUMBUS, OH, 43215-3435, US

(21) Appl. No.: 10/225,373

(22) Filed: Aug. 21, 2002

(51) Int. Cl. H05K 7/20

(52) U.S. Cl. 361/719; 361/705; 174/252

(57) ABSTRACT

An improved heat sink for surface mounted power devices. According to one embodiment of the invention, the electrical contacts of a surface mounted power device are soldered to printed circuit board solder pads. The opposite, non-component, side of the printed circuit board is provided with thermal transfer pads, which are aligned in a parallel plane with the solder pads on the component side of the printed circuit board. The solder pads and thermal transfer pads are connected together by a number of plated through holes which provide a thermal conduction path. The thermal transfer pads are placed in proximity to a heat sink such that a high thermal conductivity exists between the surface mounted power device and the heat sink, allowing heat generated by the surface mounted power device to be conducted to the heat sink and dissipated. A thermal interface material may be used to improve thermal conductivity between the thermal transfer pads and the heat sink. A brace may also be used to apply pressure on the printed circuit board and heat sink to maximize conductivity and facilitate the transfer of heat away from the surface mounted power devices.

### FIELD

The invention relates to the cooling of components mounted to printed circuit boards, more particularly to an improved method for cooling surface mounted power devices.

### BACKGROUND

Recent advances in the assembly of printed circuit boards (“PCBs”) includes the use of surface mounted devices (“SMDs”). Surface mounted devices boast smaller package sizes than through-hole electrical and electronic components. In addition, surface mounted devices have closely-pitched electrical contacts designed to be soldered directly to solder pads on the surface of the PCB. In contrast, through-hole devices have wire leads that are inserted into holes in the PCB, soldered to “lands,” then trimmed close to the PCB. Surface mounted power devices such as, for example, metal oxide field effect transistors (“MOSFETs”), diodes, insulated gate bipolar transistors (“IGBTs”), and power resistors are capable of handling high voltages and currents. Power SMDs permit much higher component densities on PCBs by enabling the components to be mounted much closer together, facilitating the design of a wide variety of products.

A typical byproduct of surface mounted power devices is heat. Industry experience has shown that excess heat is a primary cause of failure for electrical and electronic components. However, the conventional PCBs to which surface mounted devices are attached are inherently poor thermal conductors. This limitation creates a need to provide a means for cooling surface mounted power devices. Unfortunately, due to their size, complexity and added cost, conventional cooling techniques, such as separate heat sink devices and cooling fans, tend to negate to a large extent the advantages to be realized with the use of SMD.

A particular drawback of the higher component densities associated with surface mounted devices is the corresponding close concentration of heat-dissipating components such as surface mounted power devices. Power dissipation by a greater number of surface mounted power devices in a smaller space results in higher power densities for the PCB, increasing the total amount of heat generated. If this heat energy is not properly dissipated, the operating temperature of the surface mounted devices may rise above the levels recommended by the component manufacturers, adversely affecting circuit reliability, functionality, and performance. The higher power densities associated with surface mounted power devices, coupled with the correspondingly smaller electrical enclosures compounds the need to dissipate heat being generated inside of an enclosure by surface mounted devices.

The art contains many means and methods of reducing the operating temperature within an enclosure. Depending upon the application and the size of the enclosure, ventilation systems, such as fans or even air conditioning systems may be employed to lower the internal temperature of enclosures. Unfortunately, this cooling means is not acceptable in many situations due to size, weight, cost, and power consumption constraints. In such situations an alternative means for thermal transfer involving conduction, convection, and radiation is employed, commonly called “heat sinking” in the art. A heat sink conducts thermal energy from a heat source to another location for dissipation, usually by convection and radiation to the ambient environment. Heat sinks are typically made of a metal having high thermal conductivity, are somewhat more massive that the device being cooled, and may utilize “fins” to increase the overall surface area of the heat sink for improved dissipation of the thermal energy. In many cases the exterior of an enclosure is used as a heat sink. In the case of a small enclosure, it is generally desirable to transfer internally generated thermal energy to an externally mounted dissipation means for subsequent transfer to ambient air surrounding the heat sink.

The means of thermal energy transfer to be employed for a particular need should be easily implementable and provide for ease of assembly and disassembly in relation to the circuit board and the components being cooled. In this regard, the labor and cost savings enjoyed by assembly of PCBs populated with surface mounted power devices should not be compromised by the need to add mechanically complex heat sinks. For example, some through-hole power devices, such as power MOSFETs, IGBTs, fast recovery diodes, Schottky diodes, and power resistors are mechanically coupled to the enclosure within which the printed circuit card is mounted. The heat generated by these electrical components is transferred to the enclosure which, in turn, is mechanically coupled to an externally mounted heat sink. This is possible because the through-hole power devices are provided with a mechanical means, such as a metallic tab with a hole, which enable the devices to be bolted to a heat sink or the side of an enclosure. Unfortunately, coupling each of these devices to a heat sink via a bolt or screw is labor intensive. Compounding the problem, surface mounted power devices, such as power MOSFETs, are not typically equipped with means for mechanical coupling to an external heat sink.

What is needed is a cost effective means for providing a thermal path from surface mounted power devices within an enclosure to a heat dissipating means mounted outside of the enclosure. The thermal transfer path should be easy to assemble without adding significantly to the cost or mechanical complexity of the design and provide for even cooling of all power SMDs.

### SUMMARY

The instant invention provides a method for addressing the problem of cooling surface mounted power devices using standard manufacturing techniques in a unique fashion.

According to one embodiment of the invention, a set of electrical contacts of a surface mounted power device are soldered to conductive solder pads. The size and arrangement of the solder pads is usually recommended by the power device manufacturer, and often includes a solder pad for a metallic heat sink tab provided with many surface mounted power power devices. During the assembly process this tab is soldered to the solder pad, thus providing good thermal contact between the surface mounted power device and the solder pad to dissipate heat. In the prior art, heat sinking of surface mounted power devices is accomplished by using thick copper solder pads having a large enough surface area to dissipate the heat, since the PCB is thermally isolated. However, this consumes space on the PCB and reduces the number of surface mounted power devices that can be placed on the PCB. The present invention overcomes this limitation by providing thermal coupling of the surface mounted power devices to a remote heat sink by means of a number of plated-through holes which provide thermal conduction from the component side of the PCB to the side opposite thereto.

The opposite (“non-component”) side of the PCB is provided with thermal transfer pads which are aligned with the solder pads on the component side of the PCB. The solder pads and thermal transfer pads are, connected together by densely arranged plated through holes. The thermal transfer pads on the non-component side are thermally coupled to a heat sink, preferably in communication with the outside of the enclosure in which the PCB may be mounted. In some applications and designs the external heat sink may provide part of the structure of an enclosure. Thus, the external heat sink may be configured to be one or more sides of an enclosure.

In another embodiment of the invention, solder pads and plated through holes may be located under the body of a surface mounted power device for cooling purposes. These plated through holes may be utilized in addition to plated through holes located at the electrical contacts, or with surface mounted devices not having a heat sink tab. A thermally conductive adhesive may optionally be provided between the body of the surface mounted power device and the plated through holes if desired, to further increase thermal conductivity.

In still another embodiment, a flexible thermal interface material may optionally be provided between the thermal transfer pads and the heat sink to promote more efficient heat transfer. This flexible, non-electrically conductive material is commercially available in various thicknesses under such trade names as CHO-THERM®, RAYCHEM®, THERMALLOY®, and BERQUIST™. For thinner thermal interface materials it is preferable to utilize either a brace across the power devices or additional hold down screws to keep the PCB flat and in good thermal contact with the external heat sink. The brace may be constructed from any rigid material such as aluminum. Some thermal interface materials may be employed without the addition of a compressing brace. However, the additional cost associated with such thermal interface materials may outweigh the savings of eliminating the brace. In the alternative, the thermal interface material may be provided as a thermally conducting electrical isolator adhesive.

Another feature of the invention is to provide for an apparatus for cooling surface mounted power devices, comprising a printed circuit board having a component side and a non-component side and a plurality of solder pads placed on said component side of said printed circuit board. The solder pads are shaped to couple to a set of electrical contacts of a surface mounted power device. A plurality of thermal transfer pads are placed on the non-component side of said printed circuit board, with the thermal transfer pads being aligned with said solder pads in parallel planes. A plurality of plated through holes are located at the solder pads and extend therethrough the printed circuit board, and communicate with said solder pads and with said thermal transfer pads; and a thermally conductive heat sink, the heat sink being placed in proximity to said thermal transfer pads and configured to conduct heat away from the surface mounted power device.

### BRIEF DESCRIPTION OF THE DRAWING

FIG. 1 is a partial plan view of the top, component side of a printed circuit board showing a series of solder pads and plated through holes according to one embodiment of the invention;

FIG. 2 is a partial plan view of the bottom, non-component side of a printed circuit board showing a series of thermal transfer pads and plated through holes according to one embodiment of the invention;

FIG. 3 is an exploded sectional view showing the stack-up of an embodiment of the heat sink assembly for a surface mounted power device;

FIG. 4 is an exploded sectional view showing the stack-up of an alternate embodiment of the heat sink assembly for a surface mounted power device; and

FIG. 5 is a partial, isometric exploded view of one embodiment of the invention.

### DESCRIPTION OF THE PREFERRED EMBODIMENT(S)

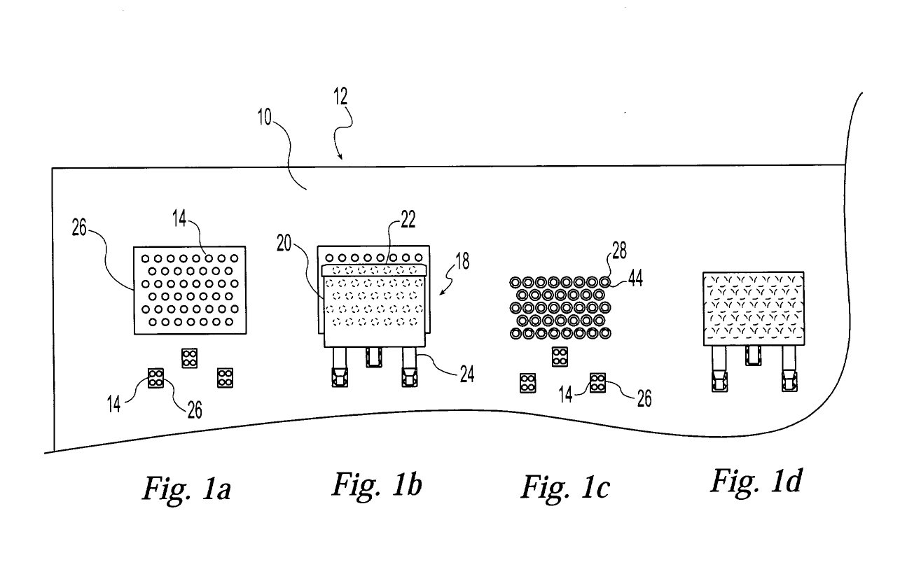

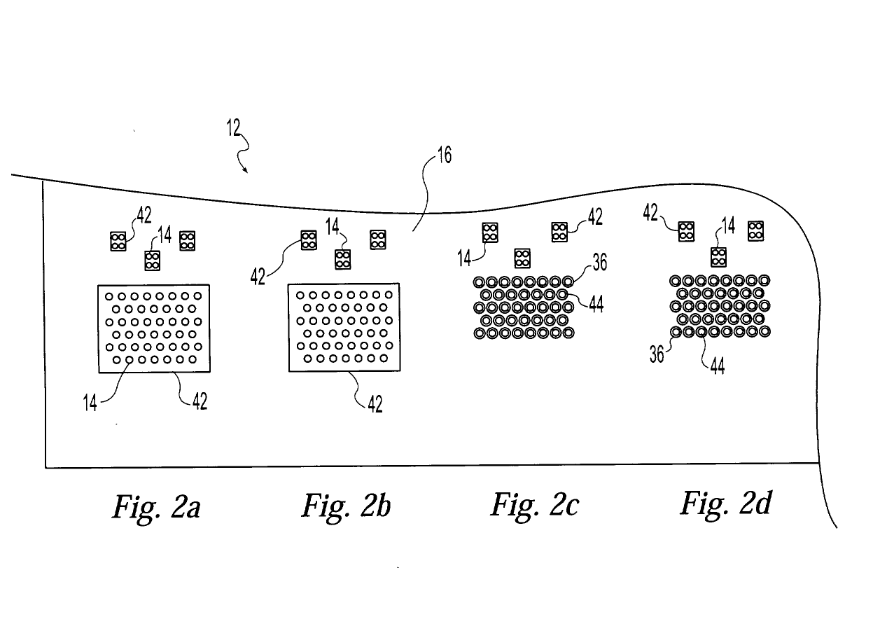

Referring to FIGS. 1 and 2, a component side 10 of a printed circuit board 12 is fabricated with a number of plated through holes 14 located at a set of solder pads 26. The plated through holes 14 extend from the solder pads 26 on component side 10 of the printed circuit board 12 to a set of thermal transfer pads 42 on a non-component side 16 of the circuit board. A surface mounted power device 18 is mounted to the component side 10 of printed circuit board 12 by positioning the surface mounted power device such that a tab 22 and a set of electrical contacts 24 of the surface mounted power device are centered over the set of solder pads 26. The tab 22 and electrical contacts 24 are then soldered to the respective solder pads 26 in any conventional manner.

The solder pads 26 and thermal transfer pads 42 are continuous, electrically and thermally conductive areas shaped as desired to couple with a surface mounted power device 18. The solder pads 26 and thermal transfer pads 42 may extend beyond the surface mounted power device 18, if desired. Increasing the surface area of the solder pads 26 and thermal transfer pads 42, and increasing the number of plated through holes 14 reduces thermal impedance, thereby improving thermal transfer. The solder pads 26, thermal transfer pads 42, and plated through holes 14 may also be used to form electrical connections to the surface mounted power device 18. The surface area of the pads 26, 42 and the number of plated through holes 14 may be sized to insure adequate current-carrying capacity for the surface mounted power device 18.

In an alternate embodiment, a number of plated through holes 44 may be located under the body 20 of the surface mounted power device 18. The plated through holes 44 may include annular rings 28 on the component side 10 of the printed circuit board 12 for increased thermal conductivity between the body 20 and the plated through holes. Likewise, annular rings 36 may be located with the plated through holes 44 on the non-component side 16 of the printed circuit board 12. Solder pads 26 and thermal transfer pads 42 may optionally be used in place of the annular rings 28, 36.

In another alternate embodiment, portions of the solder pads 26, thermal transfer pads 42, and the annular rings 28, 36 may be coated with a “solder resist” or “solder mask.” Types of solder resist include wet film, dry film, and liquid photo-imageable film. The solder resist may improve the flatness of the pads and annular rings, which is desired in order to increase the amount of surface area of the pads and annular rings in contact with adjoining surfaces, thereby reducing thermal impedance and increasing thermal conductivity.

In still another alternate embodiment, portions of the plated through holes 14, 44 may contain a thermally conductive “filler” such as bismuth, indium, or solder to increase thermal conductivity. For best thermal conductivity, care must be taken to ensure that the filler does not protrude above the annular rings 28,36 and pads 26,42. Such protrusions can cause irregular contact between the annular rings 28,36, pads 26,42, and surfaces adjoining thereto, reducing area of contact and thus thermal conductivity.

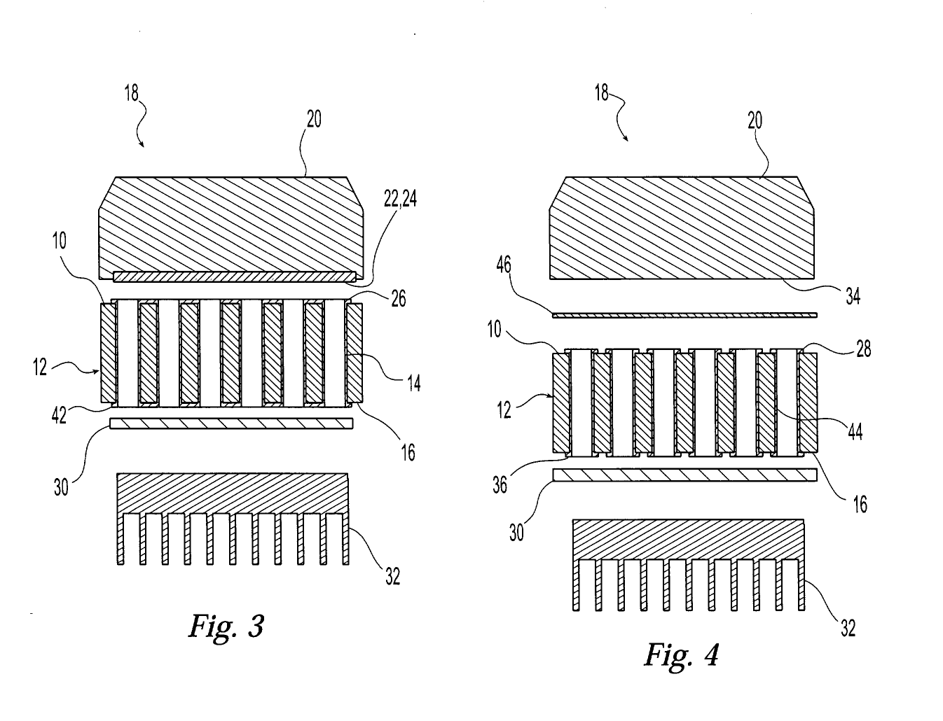

FIG. 3 shows an exploded section view of an embodiment of the heat sink assembly. A tab 22 and/or electrical contacts 24 of a surface mounted power device 18 are soldered to the solder pads 26 on the component side 10 of a printed circuit board 12. A number of plated through holes 14 are connected to the solder pads 26 and extend between the component side 10 and the non-component side 16 of the printed circuit board 12, connecting to the thermal transfer pads 42 on the non-component side of the printed circuit board.

A thermal interface material 30 may optionally be placed against the thermal transfer pads 42 to increase thermal conductivity. Thermal interface material 30 is commercially available in various thicknesses under such trade names as CHO-THERM®, RAYCHEM®, THERMALLOY®, and BERQUIST™. The thermal interface material 30 may also be formed from suitable ceramics, such as aluminum nitride. Thermal interface material 30 may also optionally provide electrical insulation for the surface mounted power device 18, if needed. A heat sink 32 is placed into contact with the thermal interface material 30 to carry away heat generated by the surface mounted power device 18 by conduction, convection, and radiation.

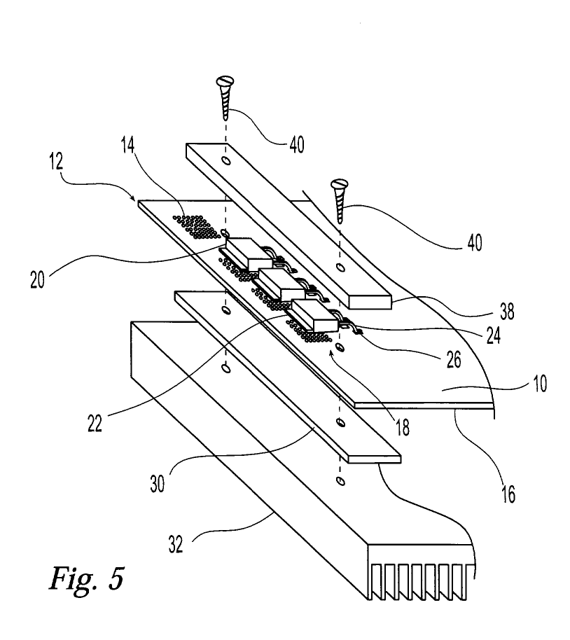

FIG. 4 shows an exploded section view of an alternate embodiment of the heat sink assembly. A number of plated through holes 44 are located on the printed circuit board 12 such that the plated through holes are positioned under the body 20 of a surface mounted power device 18. When the surface mounted power device 18 is mounted to the printed circuit board 12, a PCB-contacting surface 34 of the body 20 is placed into contact with the plated through holes 44. A thermal adhesive 46 may optionally be placed between the PCB-contacting surface 34 and the plated through holes 44 to increase thermal conductivity, if desired. The plated through holes 44 may include annular rings 28 on the component side 10 of printed circuit board 12. The annular rings 28 may be any diameter, but are preferably as large a diameter as practical to maximize thermal conductivity between the annular rings 28 and the PCB-contacting surface 34. The non-component side 16 of the printed circuit board 12 may likewise include annular rings 36 for improved thermal conductivity. A solder pad 26 (not shown) shaped to match the PCB-contacting surface 34 may be used rather than annular rings 28 if desired. Similarly, a thermal transfer pad 42 (not shown) may be used in place of annular rings 36.

A thermal interface material 30 may be placed against the annular rings 36 to increase thermal conductivity. Thermal interface material 30 may also be employed to provide electrical insulation for the surface mounted power device 18, if needed. A heat sink 32 is placed into contact with the thermal interface material 30 to carry away heat generated by the surface mounted power device 18 by conduction, convection, and radiation.

FIG. 5 is a partial, exploded view of one embodiment of the invention. Surface mounted power devices 18 are mounted to the component side 10 of the printed circuit board 12 such that the tabs 22 and electrical contacts 24 of the surface mounted power devices are placed into contact with the solder pads 26 and the plated through holes 14. Thermal interface material 30 is shown placed against the thermal transfer pads 42 (not shown) on the non-component side 16 of the printed circuit board 12. A brace 38 is shown as placed over the surface mounted power devices 18 and secured to a beat sink 32 by a plurality of screws 40 or other fastening means. When the screws 40 are tightened, the brace 38 is placed into contact with the body 20 of the surface mounted power devices 18, pressing the thermal interface material 30 into intimate contact with the thermal transfer pads 42 (not shown) on the non-component side 16 of the printed circuit board 12, increasing thermal conductivity. The thermal interface material 30 is also placed into contact with the heat sink 32, further increasing thermal conductivity.

In operation, heat generated by the surface mounted power device 18 is conducted to the tab 22 and the electrical contacts 24. The thermal energy is then conducted to the plated through holes 14, which further conduct the thermal energy to the thermal transfer pads 42. The thermal energy is transferred to the heat sink 32 via thermal interface material 30, which serves to increase thermal conductivity between the heat sink and the thermal transfer

Thermal interface material 30 may be used as an electrical insulator, if desired. As can be seen by one skilled in the art, the thermal energy from the surface mounted power device 18 is drawn away in an efficient manner by a heat sinking means that is compatible with surface mounted power devices and does not require extensive mechanical coupling.

Generally, the more plated through holes 14, 44 that are provided, the better the heat sinking performance. However, it has been observed that if the printed circuit board 12 is subsequently soldered some of the plated through holes 14, 44 will fill with solder. Solder-filled plated through holes 14, 44 can actually improve the thermal conductivity, and thus the heat dissipation efficiency, of the invention. However, it has been observed that if excess solder accumulates at the plated through holes 14, 44 during the soldering process, this can adversely affect the thermal transfer from the plated through holes, through the thermal interface material 30 due to irregular contact between the thermal transfer pads 42 and the heat sink 32. Likewise, irregular contact can occur between the PCB-contacting surface 34 and the plated through holes 44. It has also been observed that larger-sized plated through holes 14, 44 tend to fill and ball up with solder and should be avoided unless using a thicker thermal interface material 30.

While this invention has been shown and described with respect to a detailed embodiment thereof, it will be understood by those skilled in the art that various changes in form and detail thereof may be made without departing from the scope of the claims of the invention.

What is claimed is:

1. An apparatus for cooling a surface mounted power device, comprising:
a printed circuit board having a first side and a second side;
a solder pad placed on said first side of said printed circuit board, said solder pad being arranged to couple to corresponding electrical contacts of a surface mounted power device;
a thermal transfer pad placed on said second side of said printed circuit board, said thermal transfer pad being aligned with said solder pad in parallel planes;
a plurality of plated through holes located at said solder pad and extending therethrough said printed circuit board, said plated through holes communicating with said solder pad and said thermal transfer pad; and
a thermally conductive heat sink, said heat sink being placed in proximity to said thermal transfer pad for conducting heat away from said surface mounted power device.

2. The apparatus of claim 1 further including an enclosure for said printed circuit board, said heat sink forming one or more exterior surfaces of said enclosure.

3. The apparatus of claim 1 wherein a portion of said plated through holes contain a thermally conductive filler.

4. The apparatus of claim 1 wherein portions of said solder pad and said thermal transfer pad are covered with a solder resist.

5. The apparatus of claim 1 further including a thermal interface material positioned intermediate and in facing contact with said thermal transfer pad and said heat sink.

6. The apparatus of claim 5 further comprising a brace, said brace being located over said surface mounted power device and securable to said heat sink such that when secured said brace compresses said thermal transfer pad and said heat sink into substantially uniform and compressed contact with said thermal interface material.

7. The apparatus of claim 5 wherein said thermal interface material is electrically insulative.

8. The apparatus of claim 5 wherein said thermal interface material is a thermally conductive adhesive.

9. An apparatus for cooling surface mounted power devices within an enclosure, comprising:
a printed circuit board mountable within said enclosure having a first side and a second side;
a plurality of solder pads placed on said first side of said printed circuit board, said solder pads being shaped to couple to a body of corresponding surface mounted power devices;
a plurality of thermal transfer pads placed on said second side of said printed circuit board, said thermal transfer pads being aligned with said solder pads in parallel planes;
a plurality of plated through holes located at said solder pads and extending therethrough said printed circuit board, said plated through holes communicating with said solder pads and said thermal transfer pads; and
a thermally conductive heat sink, said heat sink being positioned on the second side of said printed circuit board in proximity to said thermal transfer pads, for conducting heat away from any said surface mounted power devices.

10. The apparatus of claim 9 wherein said heat sink forms at least one exterior surface of said enclosure.

11. The apparatus of claim 9 wherein a portion of said plated through holes contain solder.

12. The apparatus of claim 9 wherein said solder pads and thermal transfer pads are comprised of annular rings coaxially aligned with said plated through holes.

13. The apparatus of claim 9 further comprising a thermally conductive adhesive located between said body of said surface mounted power devices and said solder pads.

14. The apparatus of claim 9 further including a thermal interface material positioned between said thermal transfer pads and said heat sink to increase thermal conductivity between said thermal transfer pads and said heat sink.

15. The apparatus of claim 14 further comprising a brace, said brace being located over said surface mounted power devices and securable to said heat sink such that when secured said brace compresses said thermal transfer pads and said heat sink into substantially uniform and compressed contact with said thermal interface material.

16. The apparatus of claim 14 wherein said thermal interface material is electrically insulative.

17. The apparatus of claim 14 wherein said thermal interface material is a thermally conductive adhesive.

18. The apparatus of claim 14 wherein said thermal interface material is resilient.

19. An apparatus for cooling surface mounted power devices within an enclosure, comprising:
a printed circuit board having a first side and a second side;
a plurality of solder pads placed on said first side of said printed circuit board, said solder pads being shaped to couple to a set of electrical contacts and a body of a surface mounted power device;
a plurality of thermal transfer pads placed on said second side of said printed circuit board, said thermal transfer pads being aligned with said solder pads in parallel planes;
a plurality of plated through holes located at said solder pads and extending therethrough said printed circuit board, said plated through holes communicating with said solder pads and said thermal transfer pads; and
a thermally conductive heat sink, said heat sink being placed in proximity to said thermal transfer pads, said heat sink conducting heat away from said surface mounted power device.

20. An apparatus for cooling surface mounted power devices within an enclosure, comprising:
a printed circuit board having a first side and a second side;
a plurality of solder pads placed on said first side of said printed circuit board, said solder pads being shaped to couple to a set of electrical contacts and a body of a surface mounted power device;
a plurality of thermal transfer pads placed on said second side of said printed circuit board, said thermal transfer pads being aligned with said solder pads in parallel planes;
a plurality of plated through holes located at said solder pads and extending therethrough said printed circuit board, said plated through holes communicating with said solder pads and said thermal transfer pads;
a thermally conductive heat sink, said heat sink being located on said second side in proximity to said thermal transfer pads, for conducting heat away from said surface mounted power device;
a resilient thermal interface material positioned between said thermal transfer pads and said heat sink; and
a brace, said brace being located over said surface mounted power device and securable to said heat sink such that when secured said brace compresses said thermal transfer pads and said heat sink into substantially uniform and compressed contact with said thermal interface material.

21. A method for conducting heat away from surface mounted power devices within an enclosure, comprising:
providing a printed circuit board having a first side and a second side;
placing a plurality of solder pads on said first side of said printed circuit board, and shaping said solder pads to couple to a set of electrical contacts of a surface mounted power device;
placing a plurality of thermal transfer pads on said second side of said printed circuit board and aligning said thermal transfer pads with said solder pads in parallel planes;
installing a plurality of plated through holes at said solder pads such that said plated through holes extend through said printed circuit board and communicate with said solder pads and said thermal transfer pads; and
placing a thermally conductive heat sink in proximity to said thermal transfer pads, for conducting heat away from said surface mounted power device.

22. A method for conducting heat away from surface mounted power devices within an enclosure, comprising:
providing a printed circuit board having a first side and a second side;
placing a plurality of solder pads on said first side of said printed circuit board, and shaping said solder pads to couple to a body of a surface mounted power device;
placing a plurality of thermal transfer pads on said second side of said printed circuit board and aligning said thermal transfer pads with said solder pads in parallel planes;
installing a plurality of plated through holes at said solder pads such that said plated through holes extend through said printed circuit board and communicate with said solder pads and said thermal transfer pads; and
placing a thermally conductive heat sink in proximity to said thermal transfer pads and conducting heat away from said surface mounted power device.

23. A method for conducting heat away from surface mounted power devices within an enclosure, comprising:
providing a printed circuit board having a first side and a second side;
placing a plurality of solder pads on said first side of said printed circuit board, and shaping said solder pads to couple to a set of electrical contacts and a body of a surface mounted power device;
placing a plurality of thermal transfer pads on said second side of said printed circuit board and aligning said thermal transfer pads with said solder pads in parallel planes;
installing a plurality of plated through holes at said solder pads such that said plated through holes extend through said printed circuit board and communicate with said solder pads and said thermal transfer pads; and
placing a thermally conductive heat sink in proximity to said thermal transfer pads and conducting heat away from said surface mounted power device;
arranging a resilient thermal interface material between said thermal transfer pads and said heat sink; and
locating a brace that is securable to said heat sink over said surface mounted power device such that when secured said brace compresses said thermal transfer pads and said heat sink into substantially uniform and compressed contact with said thermal interface material.
